(19) United States
(12) Patent Application Publication
(10) Pub. No.: US 2006/0220064 A1
(43) Pub. Date: Oct. 5, 2006

(54) Method for manufacturing a bipolar transistor and bipolar transistor manufactured by the method

(76) Inventors: Mojtaba Joodaki, Munich (DE); Juergen Berntgen, Bad Rappenau (DE); Peter Brandl, Villach (AT); Volker Dudek, Brackenheim (DE)

Correspondence Address: MCGRATH, GEISSLER, OLDS & RICHARDSON, PLLC, P.O. BOX 1364, FAIRFAX, VA, 22038-1364, US

(21) Appl. No.: 11/387,857

(22) Filed: Mar. 24, 2006

(30) Foreign Application Priority Data
Mar. 26, 2005 (DE) 102005013982.5-33

(51) Int. Cl. H01L 31/00

(52) U.S. Cl. 257/197

(57) ABSTRACT

A bipolar transistor and a method for manufacturing the bipolar transistor is disclosed. The bipolar transistor is formed by the steps of: doping of a surface region of a substrate with a first doping to form an active emitter region; formation of at least one cavity in the substrate; application of a dielectric isolation layer to the surface of the at least one cavity in the substrate; formation of a contiguous base region with a second doping both in the at least one cavity to provide a base connection region, electrically isolated from the substrate by the dielectric isolation layer, and also at least partially on the formed active emitter region to provide a base region electrically connected to the substrate; and formation of a collector region with a third doping at least on the formed base region to provide a collector electrically connected to the formed base region.

This nonprovisional application claims priority under 35 U.S.C. § 119(a) on German Patent Application No. DE 102005013982.5-33, which was filed in Germany on Mar. 26, 2005, and which is herein incorporated by reference.

### BACKGROUND OF THE INVENTION

1. Field of the Invention

The present invention relates to a method for manufacturing a bipolar transistor and a bipolar transistor manufactured by the method.

2. Description of the Background Art

The circuit element modeling of components integrated on a semiconductor substrate plays an increasingly greater role with a rising operating frequency, because in this case performance properties, reflections at discontinuities, overlapping, and power dissipation increase. Thus, it is generally necessary to consider these effects in the modeling, particularly in the high-frequency range. Particularly in a low-resistance substrate, such as, for example, a silicon substrate, the parasitic effect of the substrate conductivity and additional capacitances cannot be disregarded.

A bipolar transistor is generally a transistor with two pn junctions, the emitter and collector, which are connected to one another by a common narrow central region, the base; it is based on the injection of minority carriers of a pn junction, usually the emitter, into the base space, the transport of these carriers through this region, and the collection, i.e., accumulation of these charge carriers at the collector junction. Both minority and majority carriers are involved in the transport. Pnp and npn transistors are differentiated depending on the sequence of the charge type of the three successive semiconductor regions.

In the normal operating state, as is present, for example, with the use of an amplifier, the emitter pn junction is operated in the flow direction and the collector-base pn junction in the blocking direction.

The converse, i.e., inverse, operating direction is possible but is used less often. In this regard, for example, in an npn transistor, electrons flow from the emitter into the base region and there is an injection of minority carriers. In this region, a portion of the electrons recombine with the holes present there, the so-called majority carriers, but the greater part of the electrons reaches the collector junction, located close to the emitter junction by so-called diffusion and/or drift, and is there drawn off as current by the collector connection. The base current effects a control of the collector current.

In the fundamental circuit, with the base as a common reference electrode, a small change in the emitter-base voltage, for example, causes a strong change in the emitter current, which is transmitted almost undiminished to the collector current and produces a correspondingly great change in the collector voltage at the load resistor. The voltage change is amplified in this way. Therefore, this change behavior is frequently also described using the term “active circuit element.”

A broad range of variation for bipolar transistors results depending on the geometric dimensions, material properties, electrical rating, manufacturing method, and intended use.

For high-frequency applications, heterobipolar transistors (HBT) are frequently used, in which at least the emitter-base junction is made as a hetero-pn junction. In the case of HBTs, the intensity of the achievable current gain is limited inter alia by the emitter efficiency. A good emitter efficiency, however, requires a high emitter doping and/or a high base resistance. Commonly used material systems are, for example, silicon-germanium (Si—Ge) emitter junctions.

Thus, there is the desire in general to improve heterobipolar transistors and their manufacturing methods, particularly SiGe HBTs, and to increase the performance for high-frequency applications. Moreover, the manufacturing costs of HBTs of this type are to be reduced.

FIG. 7 illustrates a schematic cross section of a SiGe HBT with an emitter-up structure, i.e., a structure in which the emitter 24 is integrated above the substrate and above base 25 in the transistor. As it is further evident in FIG. 7, the selectively implanted collector (so-called SIC implantation) is integrated into the substrate.

This emitter-up structure is typically realized, because very low emitter and collector resistances are required in a bipolar transistor. For example, the emitter is highly doped and the collector is realized by an arsenic n-doped layer 27, as is evident in FIG. 7. This structure makes possible an acceptable collector resistance.

In this approach, however, it turned out to be disadvantageous that, on the one hand, the collector resistance is in fact reduced, but does not produce satisfactory resistance values. Moreover, the reduced resistance values are achieved only at the expense of an increased collector-base capacitance and an increased collector-substrate capacitance, which in turn has a detrimental effect on the HF properties.

It is known to implement a silicidized layer with a low resistance instead of the arsenic n-doped layer, as a result of which a lower resistance is produced. In this way, a collector-up transistor, i.e., a transistor with a collector implemented above the base and the substrate, can be realized with a low emitter resistance. Because in this case the emitter is placed below the collector and may be higher doped than the collector, a highly phosphorus n-doped region is used. In addition, the emitter contact is placed near the highly h-doped region, and this prevents a so-called capacitive low fraction, which in turn results in a low resistance.

It is also known to manufacture an emitter-up SiGe heterobipolar transistor, which exhibits improved performance properties.

Nevertheless, in the aforementioned approaches it proved to be disadvantageous that the employed manufacturing method is costly and time-consuming. Moreover, in the aforementioned approaches, no isolation layer is provided between the emitter and base, so that the emitter-base capacitance disadvantageously assumes a very high value.

### SUMMARY OF THE INVENTION

It is therefore an object of the present invention to provide a manufacturing method for a bipolar transistor and a bipolar transistor made by the manufacturing method, which overcomes the aforementioned disadvantages and in particular assures a simpler and more cost-effective method for manufacturing a bipolar transistor with a low base resistance, low capacitances, and reduced parasitic losses.

A surface region of a semiconductor substrate can be doped with a first doping to form an active emitter region; next at least one cavity is formed in the substrate; a dielectric isolation layer can be applied to the surface of the at least one cavity in the semiconductor substrate; a contiguous semiconductor base region with a second doping is formed both in the at least one cavity to provide a base connection region, electrically isolated from the semiconductor substrate by the dielectric isolation layer, and also at least partially on the formed active emitter region to provide a base region electrically connected to the semiconductor substrate; and a semiconductor collector region with a third doping is formed at least on the formed base region to provide a collector electrically connected to the formed base region.

Thus, by a simple and cost-effective manufacturing method a bipolar transistor is manufactured in which a collector-up structure is assured and an electrical isolation between the base connection region and the substrate or emitter is created.

Thus, in comparison with the conventional approaches, the present invention has the advantage that the appearing parasitic capacitances and thereby the parasitic losses are reduced. Moreover, the base connection region can be made with a greater width in such a way that the electrical resistance of the same is advantageously reduced. The parasitic substrate capacitance is completely wiped out by the electrical decoupling from the base connection regions, the base resistances reduced, as described above, and the collector-base capacitance advantageously reduced by the collector-up structure. The bipolar transistor of the invention thereby has improved direct current and alternating current characteristics. The resistances of the base and emitter are reduced by the bipolar transistor of the invention in a simple and cost-effective manner and the parasitic losses are eliminated without a reduction in the maximum frequency of the bipolar transistor.

According to an embodiment, the base-emitter junction and/or base-collector junction can each be made as a heterostructure, for example, as a hetero-pn junction to form a heterobipolar transistor (HBT), particularly a silicon-germanium HBT. SiGe HBTs are advantageous transistors with good characteristics particularly in the high-frequency range. The HBTs have good emitter efficiencies and possess their advantages primarily in the high-frequency range, because their limiting frequencies may be far above 100 GHz.

According to another embodiment, the substrate can be made as a silicon semiconductor substrate. It is apparent to a person skilled in the art that other substrate materials may also be used, but a silicon substrate is a common substrate with good properties, which can be produced inexpensively.

The doped surface region of the substrate has a first doping, which is preferably low n-doped, for example, by phosphorus implantation. According to another embodiment, a predefined region of the substrate below the doped surface region is highly n-doped, for example, again by phosphorus implantation. Of course, other implantation materials may also be used, but in the present application phosphorus proves to be especially advantageous.

According to yet another embodiment, a first dielectric layer is formed over the substrate surface and a first indication layer, for example, a nitride layer with a predefined thickness over the first dielectric layer. This is preferably done before the application of the dielectric isolation layer in the cavity in the substrate.

Advantageously, the substrate is then etched back to form the at least one cavity, for example, by an isotropic dry etching method. In particular, two cavities at a distance from one another are formed in the substrate.

After the formation of the cavity or cavities, the dielectric isolation layer is preferably formed over the substrate to form the dielectric isolation layer on the surface of the cavity or cavities.

According to a further embodiment, the first dielectric layer and the dielectric isolation layer, as well as the first indication layer, can be structured to form growth regions for growing the contiguous base region, whereby then preferably after the formation of the growth regions a highly p-doped silicon base layer with the second doping is grown over the arrangement, for example, by an epitaxy method with the aid of the formed growth regions to form the contiguous base region in the cavity or cavities to provide the electrically isolated base connection region as well at least partially on the formed active emitter region to provide the base region.

The grown silicon layer and the dielectric isolation layer are etched back to the height of the first indication layer, for example, by a CMP (chemical mechanical polishing) method. This thereby prevents another back etching from etching off the formed necessary structures. The first indication layer thereby serves to indicate that the back-etched region was etched back to a sufficient extent by the etching procedure.

According to another embodiment, the first indication layer and the first dielectric layer on the formed active emitter region are removed, for example, by previous structuring by a photoresist layer.

According to another preferred embodiment, after the removal of the first indication layer a p-doped silicon-germanium base layer is applied over the arrangement. After the growth of the silicon-germanium layer, an n-doped silicon collector layer with the third doping is preferably grown over the arrangement and then again etched back to the height of the first indication layer, for example, by means of an isotropic dry etching process. The first indication layer is used similarly to indicate that the back-etched region has been etched back to the desired form.

After the growth of the n-doped silicon layer, for example, a second dielectric layer, for example, a silicon oxide, is applied over the arrangement. After the application of the second dielectric layer, this is removed in a structured manner to the height of the first indication layer except for the side isolation spacers, for example, by an isotropic etching process.

Next, suitable metallizations to form the connection contacts of the emitter, base, and collector are formed with the aid of the side isolation spacers. In this case, common metallization methods can be used.

According to another embodiment, the highly p-doped silicon layer grown directly on the substrate is silicidized, for example, by phosphorus implantation. This step can be carried out at the end of the manufacturing process or at an earlier time.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a-1p illustrate cross-sectional views of a bipolar transistor in different process states to depict the individual process steps according to a preferred embodiment of the present invention;

FIG. 2 illustrate schematic views of Gummel curves for a collector-up structure and an emitter-up structure;

FIG. 3 is a schematic view of simulated current gain curves for a collector-up transistor and an emitter-up transistor;

FIG. 4 is a schematic view of simulated MSG (maximum stable gain) curves for a collector-up structure and an emitter-up structure;

FIG. 5 is a schematic view of a simulated transit frequencies of a collector-up structure and an emitter-up structure;

FIG. 6 is a schematic view of simulated maximum oscillation frequencies of a collector-up structure and an emitter-up structure; and

FIG. 7 is a schematic cross-sectional view of a bipolar transistor with an emifter-up structure according to the conventional art.

### DETAILED DESCRIPTION

In the figures, the same reference characters describe the same or functionally identical components, provided it is not indicated otherwise.

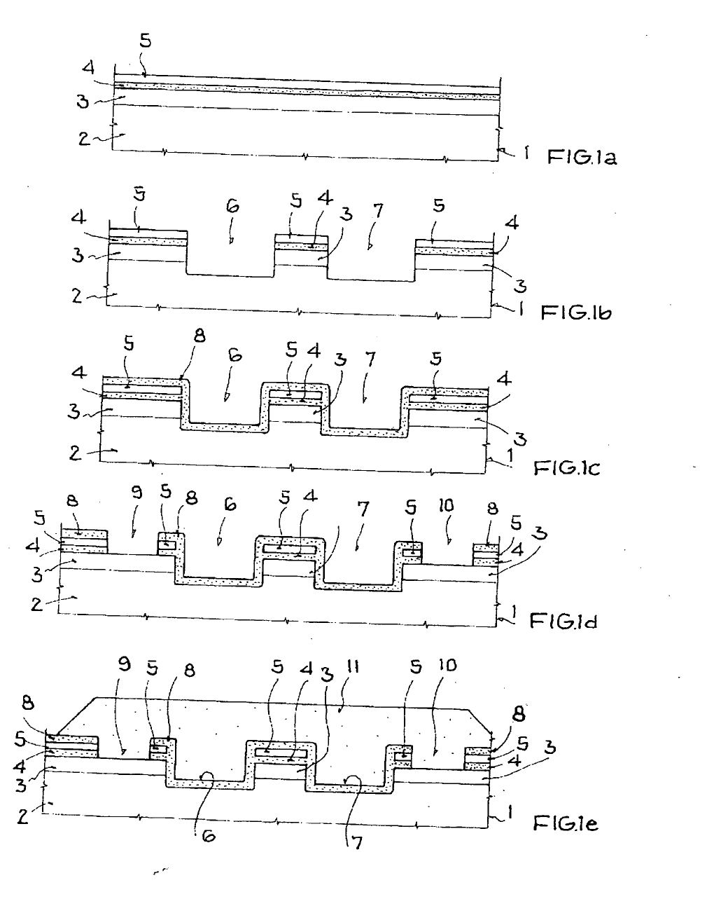

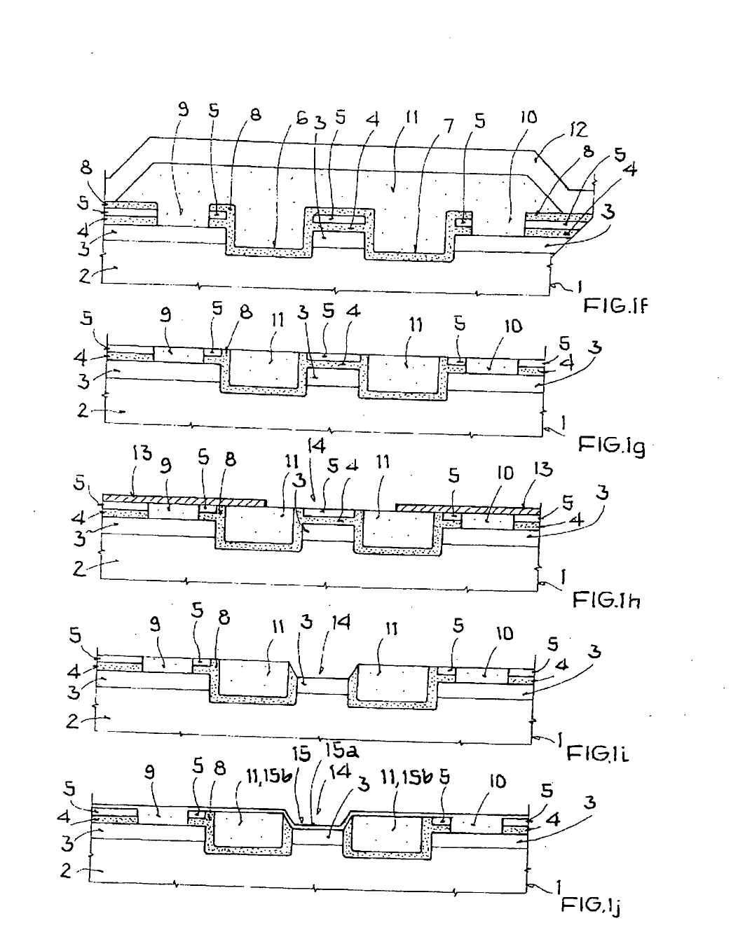

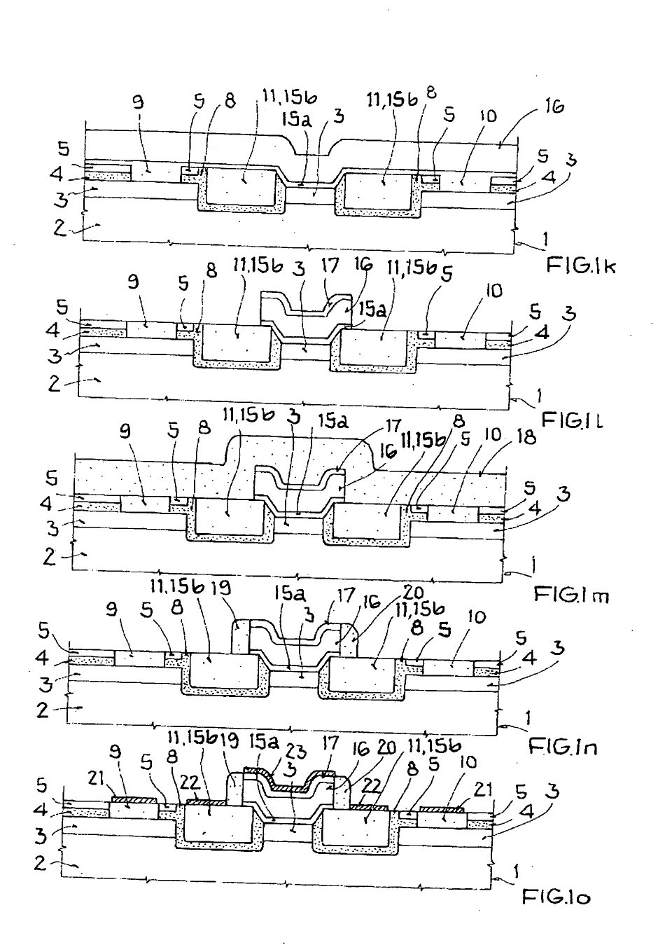

FIGS. 1a to 1p illustrate cross-sectional views of an exemplary bipolar transistor in different process states to depict the individual process steps, whereby based on FIGS. 1a to 1p a manufacturing method for a bipolar transistor according to an embodiment of the present invention is described in greater detail.

As shown in FIG. 1a, first in a substrate 1, for example, in a common silicon substrate, a highly n-doped layer 2 is formed, which is to serve later, inter alia, as an emitter. For example, to form highly n-doped layer 2 phosphorus is implanted by a suitable implantation method. A phosphorus implantation creates a lower electrical resistance, but a higher diffusion constant in regard to the doping. This requires a thicker emitter in order to make an emitter with a low doping concentration at the emitter-base junction. The implantation of phosphorus can also take place, for example, at a later time during the manufacturing process, but this could have a detrimental impact on the formation of the base and collector.

Preferably, as illustrated in FIG. 1a, the n-doped silicon layer has a low n-doped region 3, in addition to the lower highly n-doped silicon region 2. This is achieved, as stated above, preferably by a suitable implantation of, for example, phosphorus.

The thickness of the silicon layer is, for example, 250 nm, whereby the thickness is advantageously selected such that both thick external base connection regions and an emitter with a low doping concentration of approximately 3×10¹⁸ cm⁻³ at the base-emitter junction can be achieved.

Subsequently, as is also shown in FIG. 1a, a thin oxide layer 4 is formed over substrate 1 or on low n-doped region 3 of substrate 1. This can occur, for example, by a thermal method, whereby the formed thin oxide layer 4 has, for example, a thickness of 20 nm and is grown as a silicon oxide layer on substrate 1.

As shown further in FIG. 1a, an indication layer 5 is then applied to the thin oxide layer 4, which functions as a first dielectric layer 4. Indication layer 5 is made, for example, as nitride layer 5 and has a thickness of preferably 100 nm. The nitride is deposited, for example, by a deposition process on dielectric layer 4.

As shown in FIG. 1b, substrate 1 is structured next and first dielectric layer 4, indication layer 5, and the silicon are etched back at preferably two predefined regions to form cavities 6 and 7. A sufficiently known isotropic dry etching process can be used as the etching method, for example. As is evident moreover in FIG. 1b, the two back-etched cavities 6 and 7 are separated from one another by a bridge region, which ultimately serves as am active region of the bipolar transistor.

FIG. 1c illustrates an additional process step. Another oxide layer 8, advantageously a silicon oxide layer, is formed over the arrangement, i.e., over the remaining nitride layer 5 and on the surface of cavities 6 and 7. Oxide layer 8 functions as dielectric isolation layer 8.

For example, to form dielectric isolation layer 8, at first a first thin oxide layer with a thickness of, for example, 2 to 3 nm is deposited by a temperature process and thereupon a second thick oxide layer with a thickness of, for example, 100 nm by a plasma method. This has the advantage that the first thin oxide layer, which is deposited first by the thermal method, has more advantageous electrical characteristics in the junction region of the silicon layer-oxide layer. Next, by a simpler and more advantageous plasma method, this oxide layer is advantageously thickened to achieve a predefined total thickness. Thus, finally the structure shown in FIG. 1c is made.

Subsequently, in a next process step, as shown in FIG. 1d, the wafer or oxide layers 4 and 8 and nitride layer 5 are structured and back etched by, for example, an isotropic dry etching process in predefined regions 9 and 10 completely to the height of substrate 1. As a result, growth regions 9 and 10 form, as shown in FIG. 1d, which are each arranged to the side of two cavities 6 and 7.

Then, according to FIG. 1e, a highly p-doped crystalline silicon layer 11 is grown in the previously formed growth regions 9 and 10 and then a highly p-doped silicon layer is again grown thereupon in an in situ process, so that the structure shown in FIG. 1e is approximately produced. Thereby, the grown highly p-doped silicon layers fill both growth regions 9 and 10 and cavities 6 and 7. For example, a silicon epitaxy is vapor deposited to form the highly F-doped silicon layer.

Then, the entire structure is covered with a second nitride layer 12 and with use of a common etching method structured for a subsequent CMP (chemical mechanical polishing) aftertreatment.

Next, the CMP aftertreatment occurs, whereby the structure shown in FIG. 1g is formed. Thereby, first nitride layer 5 is used as indication layer 5 in such a way that second nitride layer 12, grown silicon epitaxy 11, and dielectric isolation layer 8 are removed to the height of first nitride layer 5 or indication layer 5.

In a subsequent process step, according to FIG. 1h, a photoresist layer 13 is applied over the structure and structured such that it is applied in the form shown in FIG. 1h to the arrangement. The active region arranged between the two cavities 6 and 7 and a region adjacent thereto above a portion of the cavities 6, 7 are particularly not covered by photoresist layer 13, as is evident in FIG. 1h.

Thereafter, for example, by an anisotropic etching process, first dielectric layer 4 applied between the two cavities 6 and 7 and first nitride layer 5 are removed in active region 14 according to the previously formed structuring of photoresist layer 13. Next, photoresist layer 13 is removed, for example, by acetone or a plasma method, so that the structure shown in FIG. 1i is made. The edge regions of the active region 14 are made with round edges by the anisotropic etching process, as indicated further in FIG. 1i. This rounding is advantageous for the subsequent formation of the internal base 15a.

As is illustrated in FIG. 1j, a p-doped silicon-germanium layer 15 is applied as the base region over the structure. For example, for this purpose, first a thin 5-nm silicon-germanium layer as an emitter-base spacer without doping is applied, whereby next a thicker boron p-doped silicon-germanium layer is deposited thereupon epitaxially with a thickness of, for example, 10 nm and thereupon again an undoped silicon-germanium layer as a base-collector spacer with a thickness of, for example, 10 nm.

These three aforementioned silicon-germanium layers together form silicon-germanium layer 15, shown in FIG. 1j, which is used to form the base region. Silicon-germanium layer 15 applied in active region 14 finally serves as internal base region 15a and the silicon-germanium layer deposited over cavities 6 and 7 serves as a component of the external base contact or base connection regions 15b, as depicted in FIG. 1j by way of an example.

Preferably, a lower carbon concentration percentage together with the high boron doping is used to prevent diffusing the boron out in the direction of the emitter.

FIG. 1k illustrates a subsequent process step, in which a silicon epitaxy with a low n-doping and a homogeneous thickness is grown advantageously over the arrangement in FIG. 1j, so that the structure shown in FIG. 1k is made.

Next, as illustrated in FIG. 11, a highly n-doped silicon region 17 is grown on the upper region of the low n-doped silicon epitaxy 16 in order to assure good properties for a collector connection. The high doping advantageously reduces the resistance in region 17 for contact connection of the collector. In so doing, the doping can occur, for example, again by implantation of phosphorus, arsenic, or the like.

As is also evident in FIG. 11, the grown silicon epitaxy 16, 17 is then etched back by, for example, an isotropic dry etching process. Here, first nitride layer 5 again functions as indication layer 5, which signals to the manufacturer the precise time of the back etching to the height of indication layer 5. For example, the proportion of the nitride in the etching solution can be analyzed, whereby based on the nitride concentration the progress of the etching process in the direction of the nitride layer 5 can be determined. Thereby, the back-etched layer thickness to the height of the nitride layer can be precisely regulated.

In a subsequent process step according to FIG. 1m, a second dielectric layer 18, for example, a silicon oxide layer, particularly a silicon dioxide layer, is formed over the structure, whereby, for example, first a thin oxide layer is deposited with a thickness of, for example, 2 nm by a thermal method and then a thicker oxide layer over the thin oxide layer. The thicker silicon oxide layer can be deposited, for example, by a temperature or plasma process, whereby this can be effected by a common CVD (chemical vapor deposition) method. Here, the second dielectric layer 18 is preferably applied with a uniform thickness over the structure, as shown in FIG. 1m.

Next, by, for example, an isotropic dry etching process, the second dielectric layer 18 is etched back in such a way that on the side of the grown silicon epitaxy 16, 17 in each case a spacer 19 or 20 remains, as illustrated in FIG. 1n. As a result, region 16, 17 serving as the collector on both sides has an electrically isolated spacer 19 or 20.

As shown in FIG. 1o, suitable metallizations are formed on the structure by preferably common vapor deposition and structuring methods. For example, in each case an emitter metallization 21 is formed over the p-doped silicon regions in growth regions 9 and 10, in each case a base metallization 22 is formed over silicon layers applied in cavities 6 and 7, and a collector metallization 23 above the n-doped silicon epitaxy 16, 17. To form these metallizations 21, 22 and 23, the two dielectric spacer regions 19 and 20 are advantageously used for a salicidation (Self-Aligned−Silicide=SALICIO; i.e., salicide; i.e., silicide forms only selectively and not over the entire surface), titanium being deposited, for example, and then appropriately structured.

Finally, as illustrated in FIG. 1p, a phosphorus implantation of the p-doped silicon, formed epitaxially in the two growth regions 9 and 10, occurs to assure emitter contacts in the regions of growth regions 9 and 10 with a low electrical resistance. Here, an RTA (rapid thermal annealing) method is used preferably for the silicidation. This process can also be perhaps preferred, if this provides advantageous characteristics by tempering. However, a uniform silicidation at the end of the manufacturing process is to be preferred. Instead of phosphorus, of course, a different material can be used for implantation, such as, for example, arsenide.

It is pointed out here that the aforementioned materials, layer thicknesses, and the sequence of individual process steps may be modified, as long as the structure of the bipolar transistor shown in FIG. 1p is retained. Moreover, instead of an npn junction, a pnp junction can be realized in a similar way, if desired.

As is thereby evident in FIG. 1p, the present manufacturing method of the invention creates a bipolar transistor, in which a collector-up structure is assured, whereby emitter 1, 2, 3 is electrically isolated from the external base regions 15b by dielectric isolation layer 8. As a result, a BJT (bipolar junction transistor, dt: bipolar blocking layer transistor) transistor according to the state of the art with its high parasitic losses is prevented and a bipolar transistor is created, in which the thickness of the base connections is thick enough to keep the resistance as low as possible for an advantageous electrical contact. Moreover, the direct current and alternating current efficiency of the arrangement is increased by the bipolar transistor structure of the invention.

With the present inventive concept, a collector-up SiGe heterobipolar transistor can be produced on a substrate for high-frequency applications, in which the parasitic base-emitter capacitance is greatly reduced compared with conventional bipolar transistors.

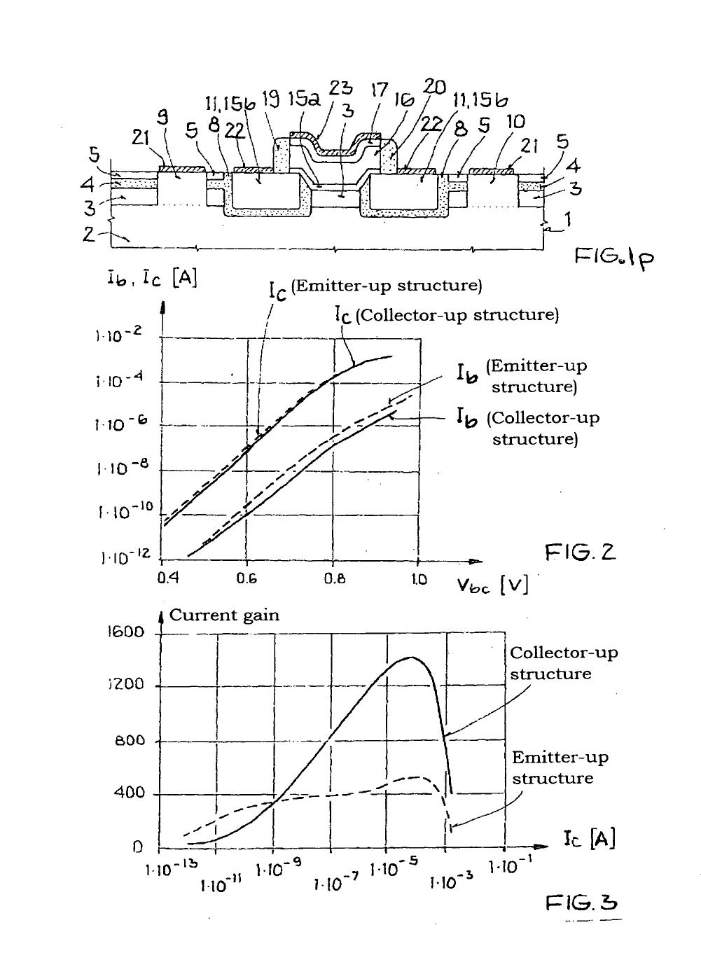

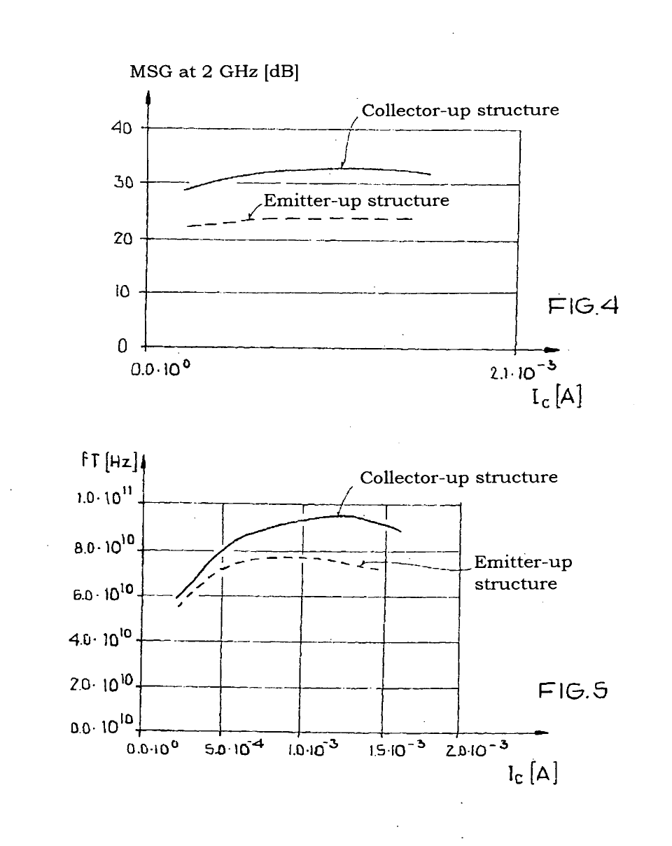

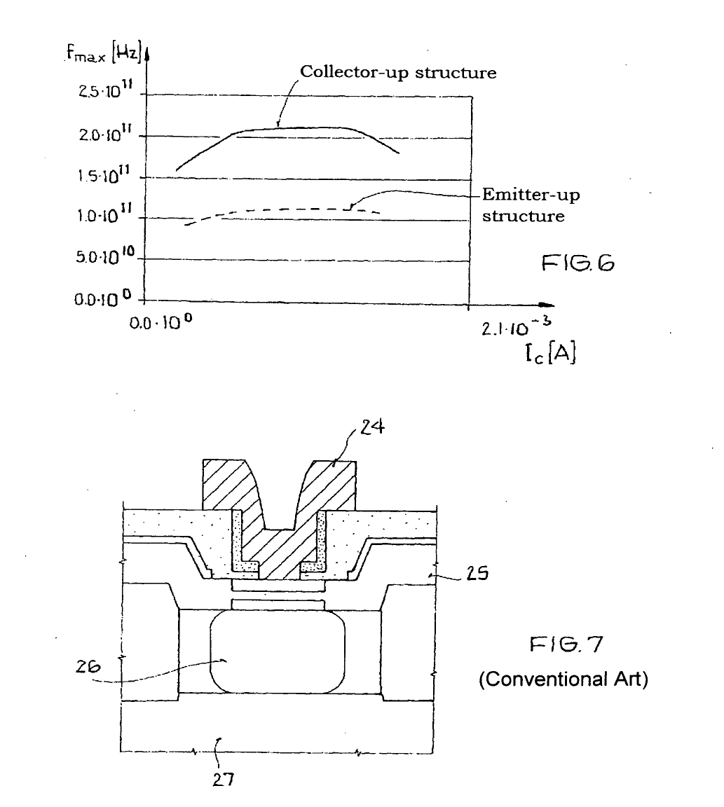

With reference to FIGS. 2 to 6, the advantages of a bipolar transistor of the invention, produced according to a manufacturing method of the present invention, are described in greater detail below in comparison with a conventional bipolar transistor.

Direct current and alternating current simulations are carried out with a collector-up transistor of the invention and an emitter-up transistor according to the state of the art with similar material properties and model parameters. For an informative comparison, the same doping profiles, germanium content, and geometric dimensions are selected for both structures. The only differences are that in the collector-up transistor, the collector is 75 nm thinner and the SIC implantation is not used, and that instead a uniform phosphorus doping of 1×10¹⁷ cm⁻³ is used. It is known that a SIC implantation improves the high-frequency performances but reduces the collector-emitter breakdown voltage.

FIGS. 2 and 3 illustrate the Gummel curves and the DC current gains for both structures, whereby the solid curves are assigned to the collector-up structure and the dashed curve to the emitter-up structure.

Because the parasitic homo-blocking layer between the monoemitter and an implanted external base has a notable effect on the base current of the emitter-up structure, the current gain of the collector-up transistor is improved. All simulations are otherwise carried out at a collector voltage of 1.5 V.

Because an SIC implantation is not used in the collector-up structure, a collector-base breakdown voltage of 11.5 V is achieved, whereas this is only 9 V for the emitter-up structure. The assigned current gain in the collector-up structure is greater, whereby the emitter-base breakdown voltages of both structures are the same and constitute about 2.5 V. A higher collector-base breakdown voltage is necessary in many high-frequency applications.

FIGS. 4, 5, and 6 illustrate the maximum stable gain (MAG) at 2 GHz, the transit frequency f_{T}, and the maximum oscillation frequency fₘₐₓ for both the emitter-up structure (dashed line) and for the collector-up structure (solid line).

The collector-base capacitance for both structures is extracted from S parameters and constitutes 1.55×10⁻¹⁴ F for the emitter-up transistor and 6.9×10⁻¹⁵ F for the collector-up transistor. This signifies a reduction of more than 55% in the parasitic capacitance of the collector-up structure of the invention compared with the conventional structure. Because the collector capacitance is effectively reduced and the effect of the parasitic homo-blocking layer transistor in the collector-up structure is reduced, the MSG value is improved by 36%, the transit frequency f_{T} by 23%, and the maximum oscillation frequency fₘₐₓ by 84%. The considerable improvement of the maximum oscillation frequency fₘₐₓ is due to the improvement of the transit frequency f_{T} and to the reduction of the collector-base capacitance and the base resistance.

Thus, the present invention creates an advantageous manufacturing method for a bipolar transistor and an advantageous bipolar transistor, produced by the manufacturing method, with a collector-up structure, whereby the substrate and emitter are each grounded, so that a parasitic substrate capacitance is avoided. Moreover, the collector-base blocking layer has a lower capacitance than previously known bipolar transistors.

In addition, the effect of the parasitic substrate is minimized and the collector-base breakdown voltages improved, as shown in the simulation curves according to FIGS. 2 to 6. The simulation results illustrate further considerable improvements of the MSG value, the transit frequency f_{T}, and the maximum oscillation frequency fₘₐₓ for the collector-up structure, as already explained above, whereby the collector-emitter breakdown voltage for both variants, i.e., for both the collector-up and emitter-up structure, has approximately the same value.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for manufacturing a bipolar transistor, the method comprising the steps of:
doping of a surface region of a substrate with a first doping to form an active emitter region;
forming at least one cavity in the substrate;
applying a dielectric isolation layer to a surface of the at least one cavity;
forming a contiguous base region with a second doping in the at least one cavity to provide a base connection region, which is electrically isolated from the substrate by the dielectric isolation layer, and also at least partially on a formed active emitter region to provide a base region, which is electrically connected to the substrate; and
forming a collector region with a third doping at least on the formed base region to provide a collector, which is electrically connected to the formed base region.

2. The method according to claim 1, wherein a base-emitter junction and/or base-collector junction are each made as a heterostructure or as a hetero-pn junction to form a heterobipolar transistor (HBT) in the form of a silicon-germanium HBT.

3. The method according to claim 1, wherein the substrate is a silicon semiconductor substrate.

4. The method according to claim 1, wherein a predefined region of the substrate below the doped surface region is highly n-doped by phosphorus implantation.

5. The method according to claim 1, wherein the surface region of the substrate, to form the first doping of the emitter region, is low n-doped by phosphorus implantation.

6. The method according to claim 1, wherein a first dielectric layer is formed over the substrate surface and wherein a first indication layer or a nitride layer with a predefined thickness is formed over the first dielectric layer before the application of the dielectric isolation layer.

7. The method according to claim 1, wherein the substrate is etched back to form the at least one cavity by an isotropic dry etching process.

8. The method according to claim 6, wherein, after the formation of the at least one cavity, the dielectric isolation layer is formed over the substrate to form the dielectric isolation layer on the surface of the at least one cavity.

9. The method according to claim 6, wherein the first dielectric layer, the dielectric isolation layer, and the indication layer are structured to form growth regions to grow the contiguous base region.

10. The method according to claim 9, wherein, after the formation of the growth regions, a highly p-doped silicon base layer with a second doping is grown over the arrangement on the basis of the formed growth regions to form the base region in the at least one cavity.

11. The method according to claim 10, wherein the grown silicon layer and the dielectric isolation layer are etched back to a height of the first indication layer by a CMP method.

12. The method according to claim 6, wherein the first indication layer and the first dielectric layer on the formed active emitter region are removed by a photoresist layer.

13. The method according to claim 12, wherein, after the removal of the first indication layer, a p-doped silicon-germanium base layer is applied.

14. The method according to claim 13, wherein, after the growth of the silicon-germanium layer, an n-doped silicon collector layer with a third doping is grown over the arrangement and is then etched back to a height of the first indication layer by an isotropic dry etching process.

15. The method according to claim 14, wherein, after the growth of the n-doped silicon layer, a second dielectric layer is applied over the arrangement.

16. The method according to claim 15, wherein, after the application of the second dielectric layer, the layer is removed in a structured manner to a height of the indication layer except for the side dielectric spacers by an isotropic dry etching process.

17. The method according to claim 16, wherein metallizations and/or salicidations are formed to form connection contacts of the emitter, base, and collector with side dielectric spacers.

18. The method according to claim 10, wherein the highly p-doped silicon layer grown directly on the substrate is silicidized by phosphorus implantation.

19. A bipolar transistor comprising:
a substrate having a surface region doped with a first doping to form an active emitter region;
at least one cavity being formed in the substrate;
a dielectric isolation layer being applied to a surface of the at least one cavity;
a contiguous base region, with a second doping, formed in the at least one cavity to form a base connection region electrically isolated from the substrate by the dielectric isolation layer, and formed at least partially on the formed active emitter region to provide a base region electrically connected to the substrate; and
a collector region, with a third doping, being formed on the formed base region to form a collector electrically connected to the formed base region.

20. The bipolar transistor according to claim 19, wherein the base-emitter junction and/or base-collector junction are a heterostructure or a hetero-pn junction that forms a heterobipolar transistor (HBT) in the form of a silicon-germanium HBT.

21. The bipolar transistor according to claim 19, wherein the substrate is a silicon semiconductor substrate.

22. The bipolar transistor according to claim 19, wherein a predefined region of the substrate below the doped surface region is highly n-doped by phosphorus implantation.

23. The bipolar transistor according to claim 19, wherein the surface region of the substrate is low n-doped by phosphorus implantation to form the first doping of the emitter region.

24. The bipolar transistor according to claim 19, wherein a first dielectric layer is formed over the substrate surface and a first indication layer or a nitride layer with a predefined thickness is formed over the first dielectric layer before the application of the dielectric isolation layer.

25. The bipolar transistor according to claim 19, wherein the substrate is etched back to form the at least one cavity by an isotropic dry etching process.

26. The bipolar transistor according to claim 24, wherein, after the formation of the at least one cavity, the dielectric isolation layer is formed over the substrate such that the dielectric isolation layer is formed on a surface of the at least one cavity.

27. The bipolar transistor according to claim 24, wherein the first dielectric layer, the dielectric isolation layer, and the indication layer are structured to form growth regions to grow the contiguous base region.

28. The bipolar transistor according to claim 27, wherein, after the formation of the growth regions, a highly p-doped silicon base layer with a second doping is grown over the arrangement with the aid of the formed growth regions to form a base region in the at least one cavity.

29. The bipolar transistor according to claim 28, wherein the grown silicon layer and the dielectric isolation layer are etched back to the height of the first indication layer by a CMP method.

30. The bipolar transistor according to claim 24, wherein the first indication layer and the first dielectric layer on the formed active emitter region are removed by a photoresist layer.

31. The bipolar transistor according to claim 30, wherein, after the removal of the first indication layer, a p-doped silicon-germanium base layer is applied over the arrangement.

32. The bipolar transistor according to claim 31, wherein, after the growth of the silicon-germanium layer, an n-doped silicon collector layer with a third doping is grown over the arrangement and is then etched back to a height of the indication layer by an isotropic dry etching process.

33. The bipolar transistor according to claim 32, wherein, after the growth of the n-doped silicon layer, a second dielectric layer is applied over the arrangement.

34. The bipolar transistor according to claim 33, wherein, after the application of the second dielectric layer, the second dielectric layer is removed in a structured manner to the height of the indication layer, except for side dielectric spacers, by an isotropic dry etching process.

35. The bipolar transistor according to claim 34, wherein metallizations and/or salicidations are formed to form connection contacts of the emitter, base, and collector with the aid of the side dielectric spacers.

36. The bipolar transistor according to claim 28, wherein the highly p-doped silicon layer grown directly on the substrate is silicidized by phosphorus implantation.
